(19) United States
(12) Patent Application Publication
(10) Pub. No.: US 2023/0094328 A1
(43) Pub. Date: Mar. 30, 2023

(54) DEPOSITION METHOD AND DEPOSITION APPARATUS

(71) Applicant: Tokyo Electron Limited, Tokyo (JP)

(72) Inventors: Takashi CHIBA, Iwate (JP); Jun SATO, Iwate (JP)

(21) Appl. No.: 17/931,957

(22) Filed: Sep. 14, 2022

(30) Foreign Application Priority Data
Sep. 30, 2021 (JP) 2021-161577

(51) Int. Cl. C23C 16/455; C23C 16/458; H01J 37/32; C23C 16/34

(52) U.S. Cl. CPC C23C 16/45536; C23C 16/4584; H01J 37/32449; C23C 16/345; H01J 2237/3321

(57) ABSTRACT

A deposition method includes (a) forming a film including silicon (Si), oxygen (O), and nitrogen (N) on a substrate; and (b) supplying a plasma generating gas including Ar gas and exposing the substrate having the film formed thereon to a plasma generated from the plasma generating gas, wherein a concentration of the nitrogen in the film is adjusted by switching to including a nitriding gas in the plasma generating gas or switching to not including the nitriding gas in the plasma generating gas.

### CROSS-REFERENCE TO RELATED APPLICATIONS

This application is based on and claims priority to Japanese Patent Application No. 2021-161577, filed on Sep. 30, 2021, the entire contents of which are incorporated herein by reference.

### BACKGROUND OF THE INVENTION

### 1. Field of the Invention

The disclosure herein relates to a deposition method and a deposition apparatus.

### 2. Description of the Related Art

There is known a technique by which a silicon oxide film is modified by using a plasma obtained from a noble gas after the silicon oxide film is formed (see Patent document 1, for example).

### RELATED-ART DOCUMENTS

Patent Documents
Patent Document 1: Japanese Laid-open Patent Application Publication No. 2014-090181

### SUMMARY OF THE INVENTION

According to an embodiment of the present disclosure, a deposition method includes (a) forming a film including silicon (Si), oxygen (O), and nitrogen (N) on a substrate; and (b) supplying a plasma generating gas including Ar gas and exposing the substrate having the film formed thereon to a plasma generated from the plasma generating gas, wherein a concentration of the nitrogen in the film is adjusted by switching to including a nitriding gas in the plasma generating gas or switching to not including the nitriding gas in the plasma generating gas.

### BRIEF DESCRIPTION OF THE DRAWINGS

Other objects and further features of the present invention will be apparent from the following detailed description when read in conjunction with the accompanying drawings, in which:

FIG. 1 is a cross-sectional view illustrating an example configuration of a deposition apparatus according to an embodiment;

FIG. 2 is a plan view of the deposition apparatus of FIG. 1;

FIG. 3 is a cross-sectional view of the deposition apparatus of FIG. 1, which is taken along the concentric circle of a rotary table;

FIG. 4 is a cross-sectional view of a plasma source provided in the deposition apparatus of FIG. 1;

FIG. 5 is an exploded perspective view of the plasma source provided in the deposition apparatus of FIG. 1;

FIG. 6 is a perspective view of an example of a housing of the plasma source of FIG. 5;

FIG. 7 is another cross-sectional view of the plasma source provided in the deposition apparatus of FIG. 1;

FIG. 8 is an enlarged perspective view of third processing gas nozzles provided in a plasma processing region;

FIG. 9 is a plan view of an example of the plasma source of FIG. 5;

FIG. 10 is a perspective view illustrating a portion of a Faraday shield provided in the plasma source;

FIG. 11 is a flowchart illustrating an example of a deposition method according to an embodiment;

FIG. 12 is a drawing illustrating measurement results of the refractive indices of SiON films;

FIG. 13 is a drawing illustrating measurement results of the film thicknesses of the SiON films;

FIG. 14 is a drawing illustrating measurement results of the refractive indices of SiON films in different plasma processing conditions;

FIG. 15 is a drawing illustrating the concentration of nitrogen and the concentration oxygen in each of the SiON films, which are calculated based on FIG. 14; and

FIG. 16 is a drawing illustrating measurement results of the film thicknesses of the SiON films in the different plasma processing conditions.

### DESCRIPTION OF THE EMBODIMENTS

In the following, non-limiting exemplary embodiments of the present disclosure will be described with reference to the accompanying drawings. In the drawings, the same or corresponding parts are denoted by the same or corresponding reference numerals and the description thereof will not be repeated.

### [Deposition Apparatus]

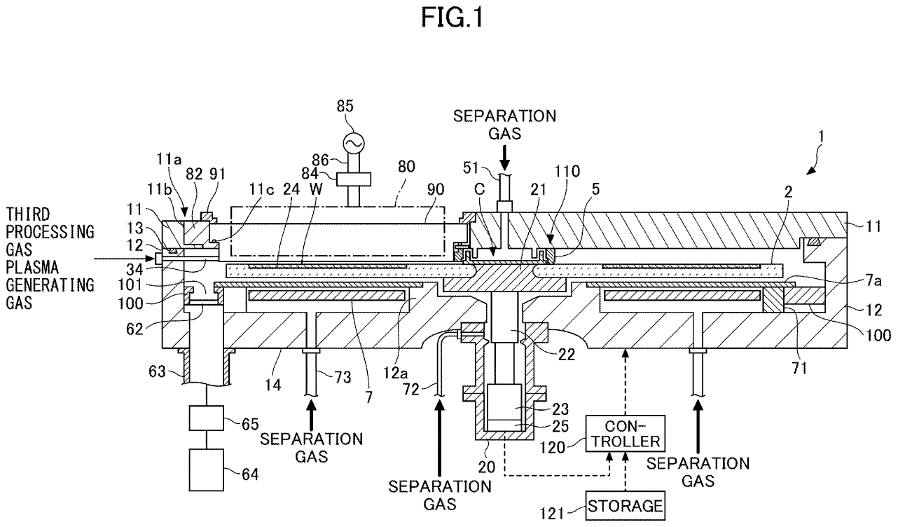

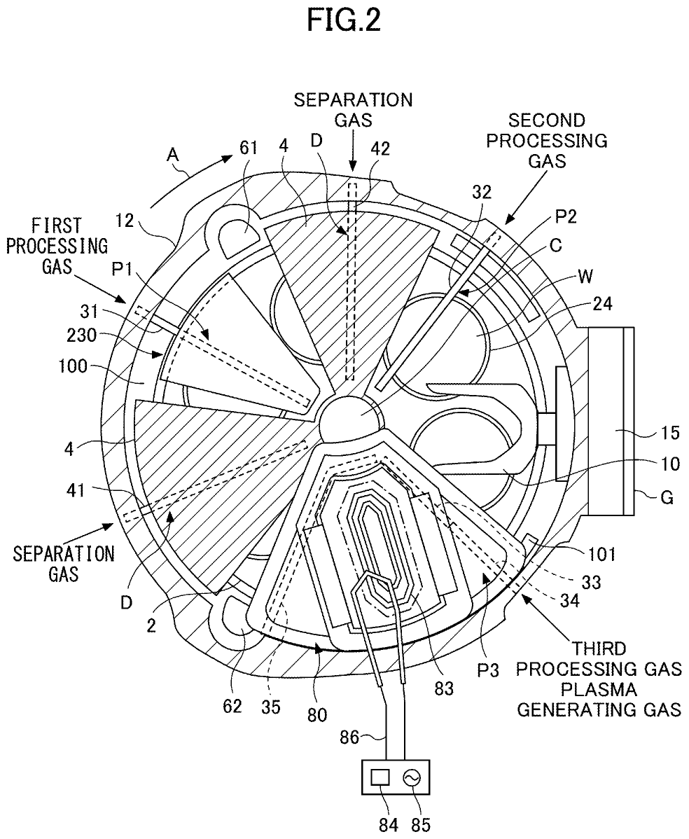

An example configuration of a deposition apparatus according to an embodiment will be described with reference to FIG. 1 through FIG. 10. FIG. 1 is a cross-sectional view illustrating an example configuration of a deposition apparatus according to an embodiment. FIG. 2 is a plan view of the deposition apparatus of FIG. 1. In FIG. 2, a top plate is not depicted for convenience of description.

As illustrated in FIG. 1, the deposition apparatus includes a vacuum chamber 1 having a substantially circular shape in a plan view and a rotary table 2 disposed in the vacuum chamber 1. The rotary table 2 has a center of rotation at the center of the vacuum chamber 1 and causes a wafer W to revolve.

The vacuum chamber 1 is a processing chamber configured to accommodate the wafer W and perform a deposition process for depositing a thin film on the surface of the wafer W. The vacuum chamber 1 includes a top plate 11 and a chamber body 12. The top plate 11 is disposed to face recessed portions 24, which will be described later, of the rotary table 2. A seal member 13 having a ring shape is provided on the peripheral edge of the upper surface of the chamber body 12. The top plate 11 is detachably attachable to the chamber body 12. The diameter (inner diameter) of the vacuum chamber 1 in a plan view is not particularly limited, and may be, for example, approximately 1100 mm.

A separation gas supplying pipe 51 is connected to a center portion of the upper surface of the vacuum chamber 1. The separation gas supplying pipe 51 supplies a separation gas to inhibit mixing of different processing gases in a central region C in the vacuum chamber 1.

A center portion of the rotary table 2 is fixed to a core portion 21 having a substantially cylindrical shape. The lower surface of the core portion 21 is connected to a rotational shaft 22 that extends in the vertical direction. In addition, the rotary table 2 is configured to rotate by a driving unit 23 about a vertical axis with respect to the rotational shaft 22 in a clockwise direction in the example as illustrated in FIG. 2. The diameter of the rotary table 2 is not particularly limited, and may be, for example, approximately 1000 mm.

The driving unit 23 includes an encoder 25 that detects the rotation angle of the rotational shaft 22. In the embodiment, the rotation angle of the rotational shaft 22, detected by the encoder 25, is transmitted to a controller 120 and used by the controller 120 to identify the position of the wafer W placed in each of the recessed portions 24 of the rotary table 2.

The rotational shaft 22 and the driving unit 23 are accommodated in a casing 20. A flange portion situated on the upper side of the casing 20 is airtightly attached to the lower surface of the bottom portion 14 of the vacuum chamber 1. Further, a purge gas supplying pipe 72 is connected to the casing 20 to supply Ar gas and the like as a purge gas (separation gas) to a region below the rotary table 2.

A protruding portion 12a having a ring shape is formed on the bottom portion 14 of the vacuum chamber 1 along the outer periphery of the core portion 21, and extends toward the rotary table 2 from the lower side.

Each of the recessed portions 24 has a circular shape, and is formed in the surface of the rotary table 2. The wafer W having a diameter of, for example, 300 mm can be placed in each of the recessed portions 24. The recessed portions 24 are provided at a plurality of positions, for example, six positions along the rotational direction (direction indicated by an arrow A in FIG. 2) of the rotary table 2. Each of the recessed portions 24 has an inner diameter slightly greater, specifically, by approximately 1 mm to 4 mm, than the diameter of the wafer W. The depth of each of the recessed portions 24 is configured to be nearly equal to the thickness of the wafer W or greater than the thickness of the wafer W. Therefore, when the wafer W is placed in each of the recessed portions 24, the surface of the wafer W and the surface of a flat region of the rotary table 2, where the wafer W is not placed, are at the same height, or the surface of the wafer W is lower than the surface of the flat region of the rotary table 2. In addition, through holes (not illustrated) through which three lifting pins, which will be described later, pass are formed in the bottom surface of each of the recessed portions 24. The three lifting pins are configured to raise and lower the wafer W by pushing the wafer W from the lower side.

As illustrated in FIG. 2, a first processing region P1, a second processing region P2, and a third processing region P3 are provided so as to be spaced apart from one another along the rotational direction of the rotary table 2. At positions above the recessed portions 24 of the rotary table 2, a plurality of gas nozzles, made of, for example, quartz, are arranged radially at intervals in the circumferential direction of the vacuum chamber 1. In the present embodiment, the plurality of gas nozzles include a first processing gas nozzle 31, a second processing gas nozzle 32, third processing gas nozzles 33 to 35, and separation gas nozzles 41 and 42.

The first processing gas nozzle 31, the second processing gas nozzle 32, the third processing gas nozzles 33 to 35, and the separation gas nozzles 41 and 42 are disposed between the rotary table 2 and the top plate 11. Each of the first processing gas nozzle 31, the second processing gas nozzle 32, the third processing gas nozzles 33 and 34, and the separation gas nozzles 41 and 42 are attached so as to face the rotary table 2 and extend horizontally from the outer peripheral wall of the vacuum chamber 1 toward the central region C. The third processing gas nozzle 35 extends from the outer peripheral wall of the vacuum chamber 1 toward the central region C, and subsequently, the third processing gas nozzle 35 is linearly bent and extends in the counterclockwise direction (in the opposite direction of the rotational direction of the rotary table 2) so as to conform to the central region C. In the example illustrated in FIG. 2, the third processing gas nozzles 33 to 35, the separation gas nozzle 41, the first processing gas nozzle 31, the separation gas nozzle 42, and the second processing gas nozzle 32 are arranged in this order in the clockwise direction (in the rotational direction of the rotary table 2) from a conveying port 15, which will be described later.

The first processing gas nozzle 31 serves as a first processing gas supply. A region below the first processing gas nozzle 31 is the first processing region P1 to which a first processing gas is supplied. The first processing gas nozzle 31 is connected to a source (not illustrated) of the first processing gas via a flow rate adjustment valve. A plurality of gas holes 36 are formed on the lower side (the side facing the rotary table 2) of the first processing gas nozzle 31 along the radial direction of the rotary table 2. The first processing gas nozzle 31 discharges the first processing gas from the plurality of gas holes 36. In the present embodiment, the first processing gas is a gas including a silicon-containing gas.

The second processing gas nozzle 32 serves as a second processing gas supply. A region below the second processing gas nozzle 32 is the second processing region P2 to which a second processing gas is supplied. The second processing gas nozzle 32 is connected to a source (not illustrated) of the second processing gas via a flow rate adjustment valve. A plurality of gas holes 36 are formed on the lower side (the side facing the rotary table 2) of the second processing gas nozzle 32 along the radial direction of the rotary table 2. The second processing gas nozzle 32 discharges the second processing gas from the plurality of gas holes 36. In the present embodiment, the second processing gas is a gas including an oxidizing gas.

Each of the third processing gas nozzles 33 to 35 serves as a third processing gas supply. A region below the third processing gas nozzles 33 to 35 is the third processing region P3 to which a third processing gas and a plasma generating gas are supplied. Each of the third processing gas nozzles 33 to 35 is connected to a source (not illustrated) of the third processing gas via a flow rate adjustment valve. A plurality of gas holes 36 are formed on the lower side (the side facing the rotary table 2) of the third processing gas nozzle 33 along the radial direction of the rotary table 2. The third processing gas nozzles 33 to 35 discharge the third processing gas from the plurality of gas holes 36 and the like. In the present embodiment, the third processing gas is a gas including a nitriding gas, and the plasma generating gas is a gas including Ar gas. Note that the third processing gas nozzles 33 to 35 may be one gas nozzle. In this case, similar to the second processing gas nozzle 32, the one gas nozzle may extend from the outer peripheral wall of the vacuum chamber 1 toward the central region C.

Each of the separation gas nozzles 41 and 42 serves as a separation gas supply. The separation gas nozzles 41 and 42 are provided so as to form separation regions D that separate the first processing region P1 from the second processing region P2 and the third processing region P3 from the first processing region P1. In the present embodiment, the separation gas is an inert gas or a noble gas.

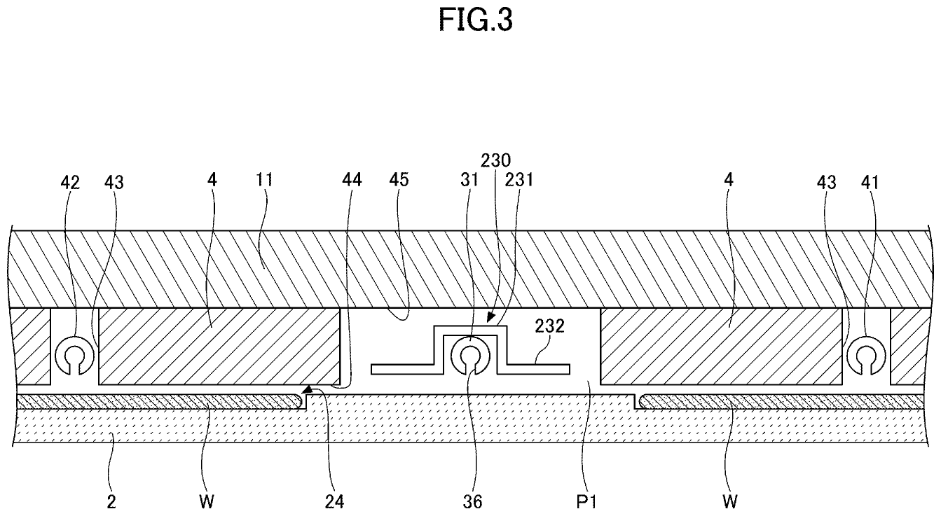

FIG. 3 is a cross-sectional view of the deposition apparatus of FIG. 1, which is taken along the concentric circle of the rotary table 2. In FIG. 3, a cross-sectional view taken from one of the separation regions D through the first processing region P1 to the other separation region D is depicted.

The top plate 11 of the vacuum chamber 1 has projecting portions 4 in the separation regions D. Each of the projecting portions 4 has a substantially circular sector shape, and is attached to the back surface of the top plate 11. In the vacuum chamber 1, flat and low ceiling surfaces (hereinafter referred to as first ceiling surfaces 44), which are the lower surfaces of the projecting portions 4, and a ceiling surface (hereinafter referred to as a second ceiling surface 45) higher than the first ceiling surfaces 44 are formed. The second ceiling surface 45 is situated between the first ceiling surfaces 44 in the circumferential direction.

As illustrated in FIG. 2, each of the projecting portions 4 forming the first ceiling surfaces 44 has a circular sector shape whose center portion is cut into an arc shape in a plan view. Grooves 43 are formed in center portions of the projecting portions 4 in the circumferential direction so as to extend in the radius direction. The separation gas nozzles 41 and 42 are accommodated in the respective grooves 43. In order to prevent processing gases from mixing with each other, the peripheral edges (on the outer edge side of the vacuum chamber 1) of the projecting portions 4 are bent in an L shape so as to face the outer end surface of the rotary table 2 and to be slightly spaced apart from the chamber body 12.

A nozzle cover 230 is provided over the first processing gas nozzle 31 such that the first processing gas flows along the wafer W, and the separation gas flows near the top plate 11 of the vacuum chamber 1 and away from the wafer W. As illustrated in FIG. 3, the nozzle cover 230 includes a cover body 231 and rectifier plates 232. The cover body 231 has a substantially box shape with an opening at the bottom in order to accommodate the first processing gas nozzle 31. The rectifier plates 232 are plate-shaped body that extend from the lower surfaces of the cover body 231 so as to be connected to the upstream and downstream sides of the rotary table 2 in the rotational direction of the rotary table 2. The side wall surface of the cover body 231 on the side closer to the center of rotation of the rotary table 2 extends toward the rotary table 2, so as to face the tip of the first processing gas nozzle 31. Further, the side wall surface of the cover body 231 on the outer edge side of the rotary table 2 is cut out so as not to interfere with the first processing gas nozzle 31. Note that the nozzle cover 230 is not necessarily provided, and may be provided as necessary.

As illustrated in FIG. 2, a plasma source 80 is provided above the third processing gas nozzles 33 to 35 such that a plasma processing gas, discharged into the vacuum chamber 1, is turned into a plasma. The plasma source 80 uses an antenna 83 to generate an inductively coupled plasma.

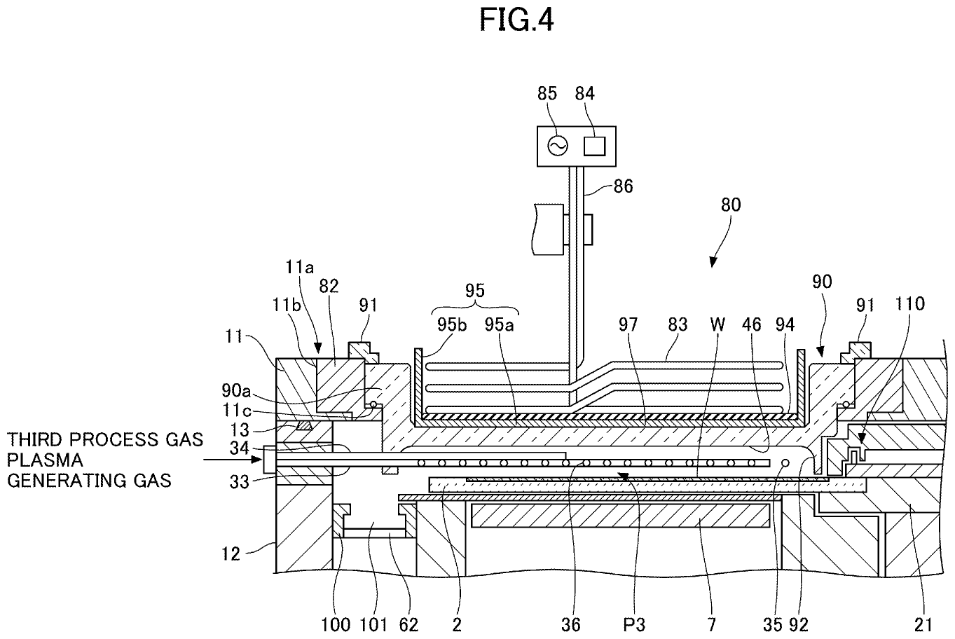

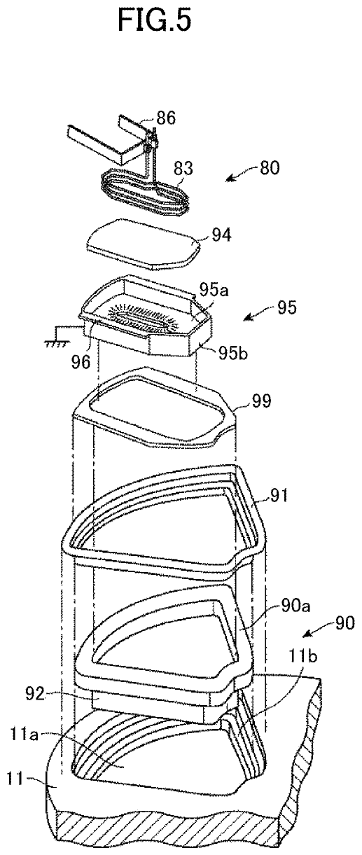

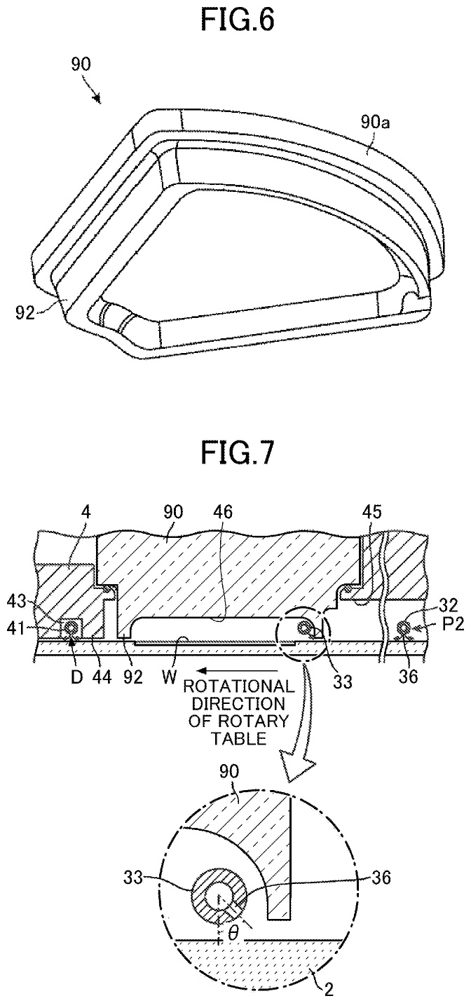

FIG. 4 is a cross-sectional view of the plasma source 80 provided in the deposition apparatus of FIG. 1. FIG. 5 is an exploded perspective view of the plasma source 80 provided in the deposition apparatus of FIG. 1. FIG. 6 is a perspective view of an example of a housing 90 of the plasma source 80 of FIG. 5.

In the plasma source 80, the antenna 83 formed of a metal wire is formed in a coil shape by, for example, being wound around the vertical axis in three turns. Further, in a plan view, the plasma source 80 is disposed across the diameter of the wafer W on the rotary table 2 so as to surround a region extending in the radial direction of the rotary table 2.

The antenna 83 is connected to an RF power source 85 having a frequency of, for example, 13.56 MHz via a matching device 84. The antenna 83 is provided so as to be airtightly isolated from the inner region of the vacuum chamber 1. In FIG. 4 and FIG. 5, connection electrodes 86 are provided so as to electrically connect the antenna 83 to the matching device 84 and to the RF power source 85.

Note that the antenna 83 may be provided with a vertically bendable configuration, a vertically movable mechanism configured to vertically bend the antenna 83 in an automatic manner, or a vertically movable mechanism configured to vertically move a portion, located closer to the center of the rotary table 2, of the antenna 83 as necessary. In FIG. 4, such configuration and mechanisms are not depicted.

As illustrated in FIG. 4 and FIG. 5, an opening 11a having a substantially circular sector shape in a plan view is formed in the top plate 11 above the third processing gas nozzles 33 to 35.

As illustrated in FIG. 4, an annular member 82 is airtightly provided in the opening 11a along the periphery of the opening 11a. The housing 90, which will be described later, is airtightly provided on the inner peripheral surface of the annular member 82. That is, the annular member 82 is provided such that the outer peripheral surface of the annular member 82 airtightly contacts an inner peripheral surface 11b of the opening 11a of the top plate 11 and the inner peripheral surface of the annular member 82 airtightly contacts a flange portion 90a of the housing 90, which will be described later. The housing 90 made of a derivative such as quartz is provided in the opening 11a via the annular member 82 such that the antenna 83 is located below the top plate 11. The lower surface of the housing 90 constitutes a ceiling surface 46 of the third processing region P3.

As illustrated in FIG. 6, an upper peripheral portion of the housing 90 constitutes the flange portion 90a that extends horizontally in a flange shape along the periphery of the housing 90. In a plan view, a center portion of the housing 90 is recessed toward the inner region of the vacuum chamber 1.

When the wafer W is positioned below the housing 90, the housing 90 is disposed across the diameter of the wafer W in the radial direction of the rotary table 2. In addition, a seal member 11c such as an O-ring is provided between the annular member 82 and the top plate 11 (see FIG. 4).

An internal atmosphere of the vacuum chamber 1 is set to be airtight by the annular member 82 and the housing 90. Specifically, the annular member 82 and the housing 90 are fitted into the opening 11a. Subsequently, the periphery of the housing 90 is pressed by a frame-shaped pressing member 91 that is formed in a frame shape along a contact portion between the upper surface of the annular member 82 and the upper surface of the housing 90. Further, the pressing member 91 is fixed to the top plate 11 with a bolt or the like (not illustrated). Accordingly, the internal atmosphere of the vacuum chamber 1 is set to be airtight. In FIG. 5, the annular member 82 is not depicted for simplicity of illustration.

As illustrated in FIG. 6, a protruding portion 92 that extends vertically toward the rotary table 2 is formed on the lower surface of the housing 90 so as to surround the third processing region P3, located below the housing 90, along the periphery of the third processing region P3. The above-described third processing gas nozzles 33 to 35 are accommodated in a region surrounded by the inner peripheral surface of the protruding portion 92, the lower surface of the housing 90, and the upper surface of the rotary table 2. The protruding portion 92, at the ends (close to the center of the vacuum chamber 1) of the third processing gas nozzles 33 to 35, is cut out in a substantially arc shape to conform to the outer shapes of the third processing gas nozzles 33 to 35.

As illustrated in FIG. 4, the protruding portion 92 is formed along the periphery of the lower surface of the housing 90 (in the third processing region P3). The protruding portion 92 allows the seal member 11c not to be directly exposed to a plasma. That is, the seal member 11c is isolated from the third processing region P3. Therefore, even if a plasma tends to be diffused from the third processing region P3, for example, toward the seal member 11c, the plasma is caused to pass under the protruding portion 92, thus allowing the plasma to be deactivated before reaching the seal member 11c.

FIG. 7 is another cross-sectional view of the plasma source 80 provided in the deposition apparatus of FIG. 1. FIG. 7 illustrates a vertical cross-sectional view of the vacuum chamber 1 taken along the rotational direction of the rotary table 2. As illustrated in FIG. 7, the rotary table 2 is rotated clockwise during a plasma process. Therefore, Ar gas tends to enter below the housing 90 via a gap between the rotary table 2 and the protruding portion 92 along with the rotation of the rotary table 2. In order to prevent the Ar gas from entering below the housing 90 via the gap, the gas is discharged from below the housing 90 toward the gap. Specifically, as illustrated in FIG. 4 and FIG. 7, the gas holes 36 of the third processing gas nozzle 33 are arranged so as to face the gap, namely face the upstream side in the rotational direction of the rotary table 2 and also face downward. An angle θ at which the gas holes 36 of the third processing gas nozzle 33 are oriented with respect to the vertical axis may be, for example, approximately 45 degrees or may be approximately 90 degrees so as to face the inner peripheral surface of the protruding portion 92, as illustrated in FIG. 7. That is, the angle θ at which the gas holes 36 are oriented may be set to within a range of approximately 45 degrees to 90 degrees depending on the intended use, such that entry of the Ar gas can be properly prevented.

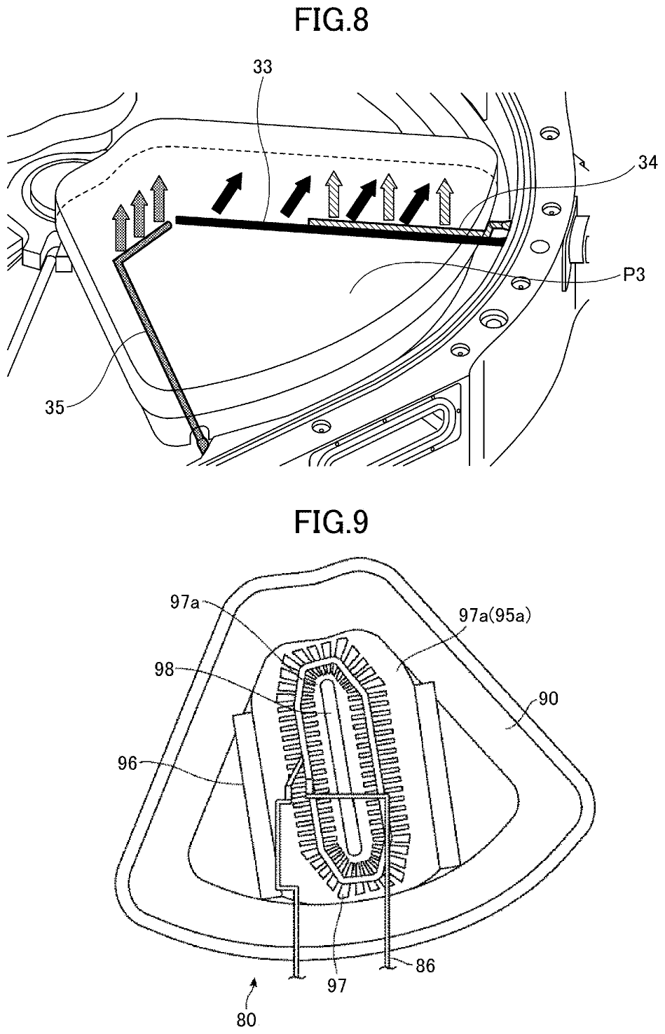

FIG. 8 is an enlarged perspective view of the third processing gas nozzles 33 to 35 provided in the third processing region P3. As illustrated in FIG. 8, the third processing gas nozzle 33 is a nozzle capable of covering the entirety of a recessed portion 24, where the wafer W is placed, and capable of supplying the plasma processing gas to the entire surface of the wafer W. The third processing gas nozzle 34 is a nozzle that is provided slightly above the third processing gas nozzle 33 while substantially overlapping the third processing gas nozzle 33, and has a length about half that of the third processing gas nozzle 33. The third processing gas nozzle 35 has a shape that extends from the outer peripheral wall of the vacuum chamber 1 along the radial direction, at the downstream side of the circular-sector-shaped third processing region P3 in the rotational direction of the rotary table 2, and is linearly bent in the vicinity of the central region C so as to conform to the central region C. In the following, for ease of distinction, the third processing gas nozzle 33 covering the entire recess portion may be referred to as a base nozzle 33, the third processing gas nozzle 34 covering only the outer side of the recess Portion may be referred to as an outer nozzle 34, and the third processing gas nozzle 35 extending to the central region may be referred to as an axis-side nozzle 35.

The base nozzle 33 is a gas nozzle for supplying the plasma processing gas to the entire surface of the wafer W. As described with reference to FIG. 7, the base nozzle 33 discharges the plasma processing gas toward the protruding portion 92 forming the side surface of the third processing region P3.

The outer nozzle 34 is a nozzle for concentratively supplying the plasma processing gas to the outer region of the wafer W.

The axis-side nozzle 35 is a nozzle for concentratively supplying the plasma processing gas to the central region of the wafer W close to the axis of the rotary table 2.

Note that if one third processing gas nozzle is used, the base nozzle 33 alone may be provided.

Next, a Faraday shield 95 of the plasma source 80 will be described in more detail. As illustrated in FIG. 4 and FIG. 5, the Faraday shield 95, which is grounded, is accommodated in the housing 90. The Faraday shield 95 is a conductive plate-like body such as a metal plate made of, for example, copper, and substantially conforms to the internal shape of the housing 90. The Faraday shield 95 includes a horizontal surface 95a and a vertical surface 95b. The horizontal surface 95a is horizontally fitted along the lower surface of the housing 90, and the vertical surface 95b is provided along the periphery of the Faraday shield 95 and extends upward from the outer edge of the horizontal surface 95a. The Faraday shield 95 may be configured to have, for example, a substantially hexagonal shape in a plan view.

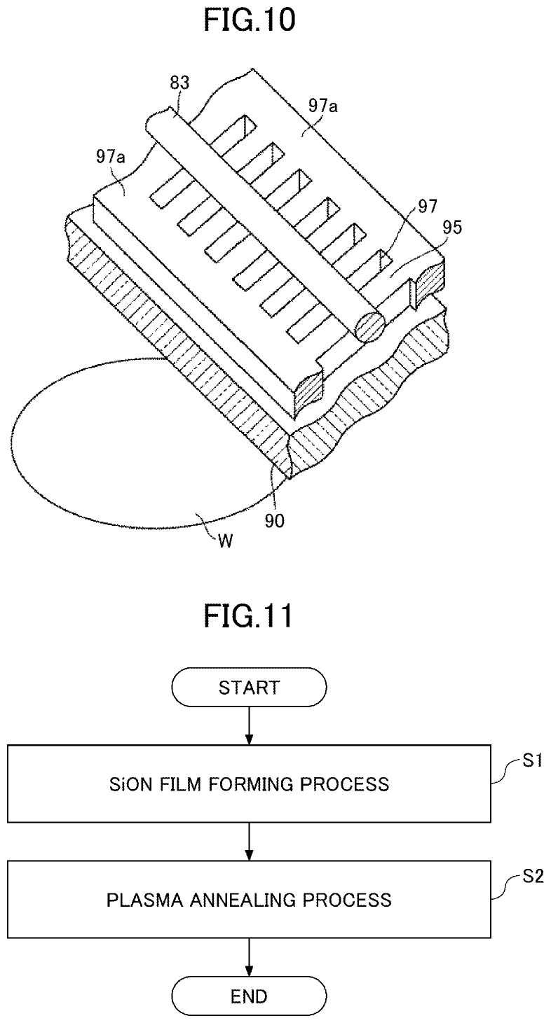

FIG. 9 is a plan view of an example of the plasma source 80 of FIG. 5, in which the detailed structure of the antenna 83 and the vertically-movable mechanism are not depicted. FIG. 10 is a perspective view illustrating a portion of the Faraday shield 95 provided in the plasma source 80.

When viewing the Faraday shield 95 from the center of rotation of the rotary table 2, the upper edge portions of the Faraday shield 95 at right and left sides extend horizontally to the right and left sides, respectively, thereby forming support portions 96. A frame-shaped body 99 is provided between the Faraday shield 95 and the housing 90 so as to support the support portions 96 from below and so as to be supported by the flange portion 90a on the central region C side of the housing 90 and on the outer peripheral side of the rotary table 2 (see FIG. 5).

If an electric field reaches the wafer W, electric wiring and the like formed inside the wafer W would be electrically damaged in some cases. Therefore, as illustrated in FIG. 10, a plurality of slits 97 are formed in the horizontal surface 95a. The slits 97 prevent, among an electric field and a magnetic field (electromagnetic fields) generated in the antenna 83, components of the electric field from being directed to the wafer W disposed below the antenna 83, and causes components of the magnetic field to reach the wafer W.

As illustrated in FIG. 9 and FIG. 10, the slits 97 are arranged below the antenna 83 so as to form a circular shape. Each of the slits 97 extends in a direction orthogonal to the winding direction of the antenna 83. The slits 97 have a width of about 1/10,000 or less of a wavelength corresponding to an RF power frequency supplied to the antenna 83. Further, conductive paths 97a, formed of a grounded conductor or the like, are disposed at the ends in the longitudinal direction of the slits 97 so as to close the open ends of the slits 97. In the Faraday shield 95, an opening 98 is formed in a region where the slits 97 are not formed, which is located below a center region surround by the antenna 83. The light emitting state of plasma is monitored through the opening 98.

As illustrated in FIG. 5, an insulating plate 94 formed of, for example, quartz and having a thickness of approximately 2 mm is stacked on the horizontal surface 95a of the Faraday shield 95, so as to ensure the insulation between the Faraday shield 95 and the plasma source 80 placed above the Faraday shield 95. That is, the plasma source 80 is disposed to cover the interior of the vacuum chamber 1 (the wafer W on the rotary table 2) through the housing 90, the Faraday shield 95, and the insulating plate 94.

Next, other components of the deposition apparatus according to the embodiment will be described.

As illustrated in FIG. 1 and FIG. 2, a side ring 100 serving as a cover body is disposed along the outer periphery of the rotary table 2 and below the rotary table 2. As illustrated in FIG. 2, a first exhaust port 61 and a second exhaust port 62 are formed in the upper surface of the side ring 100 so as to be spaced apart from each other in the circumferential direction. In other words, two exhaust ports are formed in the bottom surface of the vacuum chamber 1, and the first exhaust port 61 and the second exhaust port 62 are formed in the side ring 100 at positions corresponding to the two exhaust ports formed in the bottom surface of the vacuum chamber 1.

The first exhaust port 61 is formed at a position between the first processing gas nozzle 31 and one of the separation regions D situated at the downstream side in the rotational direction of the rotary table 2 with respect to the first processing gas nozzle 31. The second exhaust port 62 is formed at a position between the plasma source 80 and the other separation region D situated at the downstream side in the rotational direction of the rotary table 2 with respect to the plasma source 80.

The first exhaust port 61 exhausts the first processing gas and the separation gas, and the second exhaust port 62 exhausts the plasma processing gas and the separation gas. As illustrated in FIG. 1, each of the first exhaust port 61 and the second exhaust port 62 is connected to, for example, a vacuum pump 64, which serves as a vacuum exhaust mechanism, via an exhaust pipe 63 in which a pressure adjustment unit 65 such as a butterfly valve is installed.

As described above, the housing 90 is disposed to extend from the vicinity of the central region C toward the outer peripheral wall of the vacuum chamber 1. Accordingly, a gas flowing from the upstream side in the rotational direction of the rotary table 2 with respect to the second processing region P2 and then flowing toward the second exhaust port 62 may be blocked by the housing 90.

Therefore, a groove-shaped gas flow path 101, through which the gas flows, is formed in an upper surface of the side ring 100 at a position closer to the outer peripheral wall of the vacuum chamber 1 than the housing 90 is.

As illustrated in FIG. 1, a protruding portion 5 is formed at a center portion of the lower surface of the top plate 11. The protruding portion 5 is formed in a ring shape in the circumferential direction so as to be continuous with portions on the central area C side of the projecting portions 4. In addition, the lower surface of the protruding portion 5 is at the same height as the lower surfaces (first ceiling surfaces 44) of the projecting portions 4. In order to inhibit mixing of different processing gases in the central region C, a labyrinth structure 110 is provided above the core portion 21 at a position closer to the center of rotation of the rotary table 2 than the protruding portion 5 is.

As described above, the housing 90 extends to the vicinity of the central region C. Therefore, the core portion 21 supporting the center portion of the rotary table 2 is formed near the center of rotation of the rotary table 2, such that a portion of the core portion 21 above the rotary table 2 does not contact the housing 90. For this reason, different gases are more likely to be mixed in the central region C than in outer peripheral regions. Therefore, by forming the labyrinth structure 110 above the core portion 21, the flow path of gases can be blocked and thus the gases can be prevented from being mixed.

As illustrated in FIG. 1, a heater unit 7 that is a heating mechanism is provided in a space between the rotary table 2 and the bottom portion 14 of the vacuum chamber 1. The heater unit 7 is configured to heat the wafer W on the rotary table 2, for example, in the range from room temperature to approximately 700° C. via the rotary table 2. As illustrated in FIG. 1, a cover member 71 is provided at the lateral side of the heater unit 7, and a cover member 7a for covering the heater unit 7 from above is provided. Further, in the bottom portion 14 of the vacuum chamber 1, purge gas supply pipes 73 are provided below the heater unit 7 at a plurality of positions along the circumferential direction so as to purge the space where the heater unit 7 is provided.

As illustrated in FIG. 2, the conveying port 15 for transferring the wafer W between a conveying arm 10 and the rotary table 2 is formed on the side wall of the vacuum chamber 1. The conveying port 15 is configured to be opened and closed airtightly by a gate valve G.

The wafer W is transferred between the conveying arm 10 and the rotary table 2 when the recessed portion 24 is at a position facing the conveying port 15. Therefore, lifting pins and a lifting mechanism (not illustrated) are provided at positions below the rotary table 2. The lifting pins are configured to pass through the recessed portion 24 to lift the wafer W from the bottom surface of the wafer W.

Further, the deposition apparatus according to the embodiment includes the controller 120 constituted by a computer configured to control the overall operation of the deposition apparatus. The controller 120 includes a processing circuitry and a memory that stores a program for executing a substrate process as will be described later. The program includes instructions executed by the processing circuitry to cause the deposition apparatus to perform various operations. The program is installed in the memory of the controller 120 from a storage 121. The storage 121 may be a storage medium such as a hard disk, a compact disc, a magneto-optical disk, a memory card, a flexible disk, or the like.

### [Deposition Method]

A deposition method according to an embodiment in which the above-described deposition apparatus is used to form a SiON film will be described with reference to FIG. 11. The deposition method according to the embodiment is performed by the controller 120 controlling the overall operation of the deposition apparatus.

As illustrated in FIG. 11, in the deposition method according to the embodiment, a SiON film is formed by performing a SiON film forming process S1 and a plasma annealing process S2 in this order.

First, a wafer W is loaded into the vacuum chamber 1. When the wafer W is loaded, the gate valve G is opened. Then, while the rotary table 2 is rotated in an intermittent manner, the wafer W is placed on the rotary table 2 by the conveying arm 10 through the conveying port 15. After the wafer W is placed, the conveying arm 10 is moved to the outside of the vacuum chamber 1 and the gate valve G is closed.

Next, the SIGN film forming process S1 is performed. In the SiON film forming process S1, in a state in which the pressure in the vacuum chamber 1 is adjusted to a predetermined pressure by the vacuum pump 64 and the pressure adjustment unit 65, the heater unit 7 heats the wafer W to a predetermined temperature while the rotary table 2 is rotated. At this time, the separation gas nozzles 41 and 42 supply a separation gas (for example, Ar gas). The first processing gas nozzle 31 supplies a first processing gas (for example, DIPAS gas). The second processing gas nozzle 32 supplies a second processing gas (for example, a mixed gas of O₃ gas and O₂ gas). The third processing gas nozzles 33 to 35 supply a third processing gas (for example, a mixed gas of NH₃ gas and Ar gas). Further, RF power is supplied from the RF power source 85 to the antenna 83 so as to ignite and generate a plasma from the third processing gas.

In the SiON film forming process S1, in the first processing region P1, the DIPAS gas is adsorbed to the surface of the wafer W along with the rotation of the rotary table 2. Subsequently, in the second processing region P2, the DIPAS gas adsorbed to the wafer W is oxidized by the O₃ gas. As a result, one or more molecular layers of SiO₂, which is a thin film component, is formed and deposited on the wafer W. As the rotary table 2 is further rotated, the wafer W reaches the third processing region P3, and nitrogen is introduced into the molecular layers of SiO₂. Accordingly, one or more molecular layers of SiON is formed on the wafer W.

In such a state, by continuing the rotation of the rotary table 2, a cycle including the adsorption of the DIPAS gas to the surface of the wafer W, the oxidation of components of the DIPAS gas adsorbed to the surface of the wafer W, and the introduction of the nitrogen into the molecular layers of SiO₂ is repeated. That is, a SiON film is formed by an ALD method along with the rotation of the rotary table 2. After the thickness of the SiON film reaches a target film thickness, the supply of the RF power from the RF power source 85 to the antenna 83 is stopped. In addition, the supply of the first processing gas, the second processing gas, and the third processing gas is stopped.

Next, the plasma annealing process S2 is performed. In the plasma annealing process S2, in a state in which the pressure in the vacuum chamber 1 is adjusted to a predetermined pressure by the vacuum pump 64 and the pressure adjustment unit 65, the wafer W is heated by the heater unit 7 to a predetermined temperature while the rotary table 2 is rotated. At this time, the separation gas nozzles 41 and 42 supplies the separation gas (for example, Ar gas). The first processing gas nozzle 31 does not supply the first processing gas, and the second processing gas nozzle 32 supplies the second processing gas (for example, a mixed gas of O₃ gas and O₂ gas). The third processing gas nozzles 33 to 35 supply a plasma generating gas (for example, Ar gas or a mixed gas of NH₃ gas and Ar gas). Further, RF power is supplied from the RF power source 85 to the antenna 83 so as to ignite and generate a plasma from the plasma generating gas.

In the plasma annealing process S2, the concentration of nitrogen in the SiON film formed in the SiON film forming process S1 is adjusted by switching to including NH₃ gas in the plasma generating gas or switching to not including NH₃ gas in the plasma generating gas. If NH₃ gas is not included in the plasma generating gas, active species (such as Ar ions) of Ar gas, which forms a plasma, react with the SiON film, and nitrogen is removed from the SiON film, thus decreasing the concentration of nitrogen in the SiON film. Conversely, if NH₃ gas is included in the plasma generating gas, active species (such as NH₂ radicals or NH radicals) of the NH₃ gas, which forms a plasma, reacts with the SiON film, and nitrogen is introduced into the SiON film, thus increasing the concentration of nitrogen in the SiON film.

In such a state, by continuing the rotation of the rotary table 2, the SiON film formed on the wafer W is exposed to the plasma generated from the plasma generating gas, and as a result, the concentration of nitrogen in the SiON film is adjusted. Then, after a predetermined period of time elapses, the supply of the RF power from the RF power source 85 to the antenna 83 is stopped. In addition, the supply of the second processing gas and the plasma generating gas is stopped. Subsequently, the rotation of the rotary table 2 is stopped. Then, the processed wafer N is unloaded from the vacuum chamber 1, and the process ends.

In the deposition method according to the above-described embodiment, after the SiON film forming process S1 is performed, the plasma annealing process S2 is performed. In the plasma annealing process S2, the concentration of nitrogen in the SiON film is adjusted by switching to including NH₃ gas in the plasma generating gas or switching to not including NH₃ gas in the plasma generating gas. Accordingly, after the SiON film is formed, the concentration of nitrogen in the SiON film can be controlled.

Note that in the deposition method according to the above-described embodiment, the SiON film forming process S1 and the plasma annealing process S2 are performed once in this order; however, the present invention is not limited thereto. For example, the SiON film forming process S1 and the plasma annealing process S2 may be alternately repeated.

### EXAMPLES

### Example 1

In Example 1, each SiON film was formed on a silicon wafer by performing the SiON film forming process S1 and subsequently performing the plasma annealing process S2 in the above-described deposition apparatus. In Example 1, in the plasma annealing process S2, Ar gas was supplied from the third processing gas nozzles 33 to 35, without supplying NH₃ gas. The processing time of the plasma annealing process S2 was varied by 0 minutes (that is, the plasma annealing process S2 was not performed), 1 minute, 5 minutes, and 10 minutes. Next, the refractive index and the film thickness of each of the SiON films were measured. The conditions for the SiON film forming process S1 and the conditions for the plasma annealing process S2 were as follows.

### <SiON Film Forming Process S1>

Wafer temperature: 400° C.

Pressure in vacuum chamber 1: 1.8 Torr to 2.0 Torr (240 Pa to 267 Pa)

RF power: 4000 W

First processing gas nozzle 31: DIPAS gas

Second processing gas nozzle 32: Mixed gas of O₃ gas and O₂ gas

Third processing gas nozzles 33 to 35: Mixed gas of Ar gas and NH₃ gas

Rotational speed of rotary table 2: 10 rpm

### <Plasma Annealing Process S2>

Wafer temperature: 400° C.

Pressure in vacuum chamber 1: 1.8 Torr to 2.0 Torr (240 Pa to 267 Pa)

RF power: 4000 W

First processing gas nozzle 31: Not used (first processing gas was not supplied)

Second processing gas nozzle 32: Mixed gas of O₃ gas and O₂ gas

Third processing gas nozzles 33 to 35: Ar gas

Rotational speed of rotary table 2: 10 rpm

Processing time: 0 minutes, 1 minute, 5 minutes, and 10 minutes

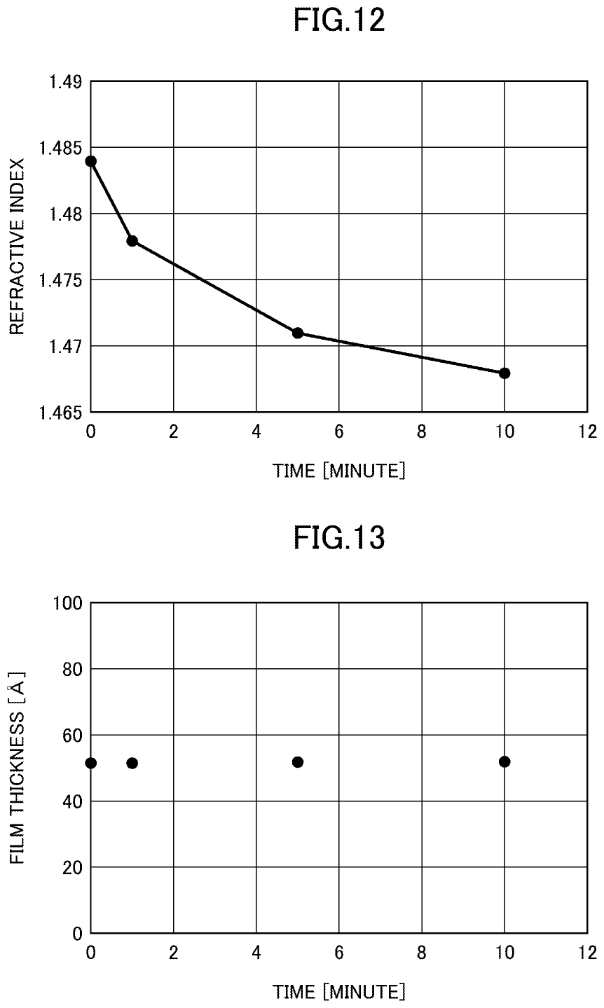

FIG. 12 is a drawing illustrating measurement results of the refractive indices of the SiON films. In FIG. 12, the horizontal axis indicates the processing time [minutes] of the plasma annealing process S2, and the vertical axis indicates the refractive index of each of the SiON films.

As illustrated in FIG. 12, it can be seen that a SiON film having a lower reflective index is formed by supplying Ar gas from the third processing gas nozzles 33 to 35 without supplying NH₃ gas in the plasma annealing process S2. In addition, it can be seen that as the processing time of the plasma annealing process S2 increases, the refractive index of the SiON film decreases. It is known that the higher the composition ratio of oxygen (O) to nitrogen (N) in the SiON film is, the lower the refractive index is. Considering this, it can be said that the composition ratio of oxygen to nitrogen in the SiON film can be increased by supplying Ar gas from the third processing gas nozzles 33 to 35 without supplying NH₃ gas in the plasma annealing process S2 and by increasing the processing time of the plasma annealing process S2. Therefore, it is confirmed that the concentration of nitrogen and the concentration of oxygen in the SiON film can be controlled by supplying Ar gas from the third processing gas nozzles 33 to 35 without supplying NH₃ gas in the plasma annealing process S2 and by varying the processing time of the plasma annealing process S2.

FIG. 13 is a drawing illustrating measurement results of the film thicknesses of the SiON films. In FIG. 13, the horizontal axis indicates the processing time [minutes] of the plasma annealing process S2, and the vertical axis indicates the film thicknesses [Å] of the SIGN films.

As illustrated in FIG. 13, it can be seen that the film thicknesses of the SiON films are approximately the same even when the processing time of the plasma annealing process S2 is varied. Therefore, it can be said that performing the plasma annealing process S2 has little influence on the film thicknesses of the SiON films. Although not illustrated, in-plane uniformities of the film thicknesses of the SIGN films are approximately the same even when the processing time of the plasma annealing process S2 is varied. Therefore, it can also be said that performing the plasma annealing process S2 has little influence on the in-plane uniformities of the film thicknesses of the SiON films.

### Example 2

In Example 2, in the above-described deposition apparatus, SiON films were formed under seven different conditions (conditions 1 to 7), and the refractive indices and the film thicknesses of the SiON films were measured. Further, the concentration of nitrogen and the concentration oxygen of each of the SiON films, which correspond to the measured refractive index of each of the SiON films, were calculated by using a known relationship between the refractive index versus the concentration of nitrogen and the concentration of oxygen of a SiON film.

In the condition 1, after the SiON film forming process S1 is performed, the plasma annealing process S2 is not performed.

In the conditions 2 to 5, after the SiON film forming process S1 is performed, the plasma annealing process S2 is performed. Specifically, in the condition 2, the second processing gas nozzle 32 supplied O₃ gas and O₂ gas and the third processing gas nozzles 33 to 35 supplied Ar gas without supplying NH₃ gas in the plasma annealing process S2. In the condition 3, the second processing gas nozzle 32 supplied O₂ gas without supplying O₃ gas and the third processing gas nozzles 33 to 35 supplied Ar gas without supplying NH₃ gas in the plasma annealing process S2. In the condition 4, the second processing gas nozzle 32 supplied O₂ gas without supplying O₃ gas and the third processing gas nozzles 33 to 35 supplied Ar gas and NH₃ gas in the plasma annealing process S2. In the condition 5, the second processing gas nozzle 32 supplied O₂ gas and O₃ gas and the third processing gas nozzles 33 to 35 supplied Ar gas and NH₃ gas in the plasma annealing process S2.

In the conditions 6 and 7, after the SiON film forming process S1 is performed, an annealing process that does not use a plasma is performed instead of the plasma annealing process S2. In the condition 6, the second processing gas nozzle 32 supplied O₂ gas and O₃ gas and the third processing gas nozzles 33 to 35 supplied Ar gas without supplying NH₃ gas in the annealing process. In the condition 7, the second processing gas nozzle 32 supplied O₂ gas without supplying O₃ gas and the third processing gas nozzles 33 to 35 supplied Ar gas without supplying NH₃ gas in the annealing process.

The conditions for the SIGN film forming process S1, the conditions for the plasma annealing process S2, the conditions for the annealing process were as follows.

### <SiON Film Forming Process S1>

Wafer temperature: 400° C.

Pressure in vacuum chamber 1: 1.8 Torr to 2.0 Torr (240 Pa to 267 Pa)

RF power: 4000 W

First processing gas nozzle 31: DIPAS gas

Second processing gas nozzle 32: Mixed gas of O₃ gas and O₂ gas

Third processing gas nozzles 33 to 35: Mixed gas of Ar gas and NH₃ gas

Rotational speed of rotary table 2: 10 rpm

### <Plasma Annealing Process S2>

Wafer temperature: 400° C.

Pressure in vacuum chamber 1: 1.8 Torr to 2.0 Torr (240 Pa to 267 Pa)

BF power: 4000 W

First processing gas nozzle 31: Not used (first processing gas was not supplied)

Second processing gas nozzle 32: Mixed gas of O₃ gas and O₂ gas, or O₂ gas

Third processing gas nozzles 33 to 35; Ar gas or mixed gas of Ar gas and NH₃ gas

Rotational speed of rotary table 2: 10 rpm

### <Annealing Process>

Wafer temperature: 400° C.

Pressure in vacuum chamber 1: 1.8 Torr to 2.0 Torr (240 Pa to 267 Pa)

RF power: 0 W

First processing gas nozzle 31: Not used (first processing gas was not supplied)

Second processing gas nozzle 32: Mixed gas of O₃ gas and O₂ gas, or O₂ gas

Third processing gas nozzles 33 to 35: Ar gas Rotational speed of rotary table 2: 10 rpm

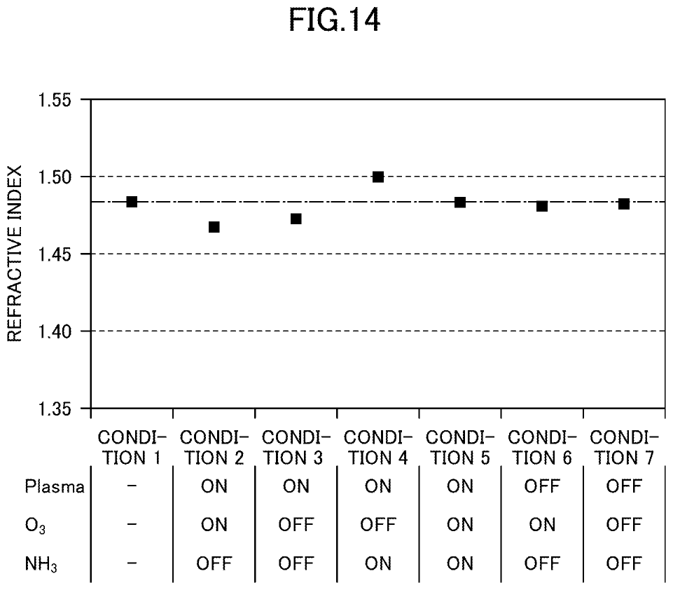

FIG. 14 is a drawing illustrating measurement results of the refractive indices of the SiON films in the conditions 1 to 7.

As illustrated in FIG. 14, it can be seen that the refractive index of the SiON film in each of the conditions 2 and 3 is lower than that of the condition 1. That is, it can be seen that the refractive index of the SiON film becomes lower when Ar gas is supplied from the third processing gas nozzles 33 to 35 than when the plasma annealing process S2 is not performed. In particular, it can be seen that the refractive index of the SiON film in the condition 2 is lower than that of the condition 3. That is, it can be seen that the refractive index of the SiON film becomes lower when O₃ gas is supplied from the second processing gas nozzle 32 in the plasma annealing process S2 than when O₃ gas is not supplied from the second processing gas nozzle 32 in the plasma annealing process S2.

As illustrated in FIG. 14, it can be seen that the refractive index of the SiON film in the condition 4 is higher than that of the condition 1. That is, it can be seen that the refractive index of the SiON film becomes higher when O₃ gas is not supplied from the second processing gas nozzle 32 and Ar gas and NH₃ gas are supplied from third processing gas nozzles 33 to 35 in the plasma annealing process S2 than when the plasma annealing process S2 is not performed.

The above results indicate that the refractive index of a SiON film can be adjusted by switching to including NH₃ gas in a gas supplied from the third processing gas nozzles 33 to 35 or switching to not including NH₃ gas in the gas supplied from the third processing gas nozzles 33 to 35 in the plasma annealing process S2.

Further, as illustrated in FIG. 14, it can be seen that the refractive index of the SiON film in the condition 5 substantially does not change as compared to that of the condition 1. That is, it can be seen that the refractive index of the SiON film substantially does not change between when O₃ gas is supplied from the second processing gas nozzle 32 and Ar gas and NH₃ gas are supplied from third processing gas nozzles 33 to 35 in the plasma annealing process S2 and when the plasma annealing process S2 is not performed. Therefore, it is considered that, in order to adjust the refractive index of a SiON film in the plasma annealing process S2, it is required not to supply O₃ gas from the second processing gas nozzle 32.

Further, as illustrated in FIG. 14, it can be seen that the refractive index of the SiON film in each of the conditions 6 and 7 substantially does not change as compared to that of the condition 1. That is, it can be seen that the refractive index of the SiON film substantially does not change between when the annealing process is performed instead of the plasma annealing process S2 and when the annealing process is not performed. Therefore, it is considered that, in order to adjust the refractive index of a SiON film, it is required to perform the plasma annealing process S2.

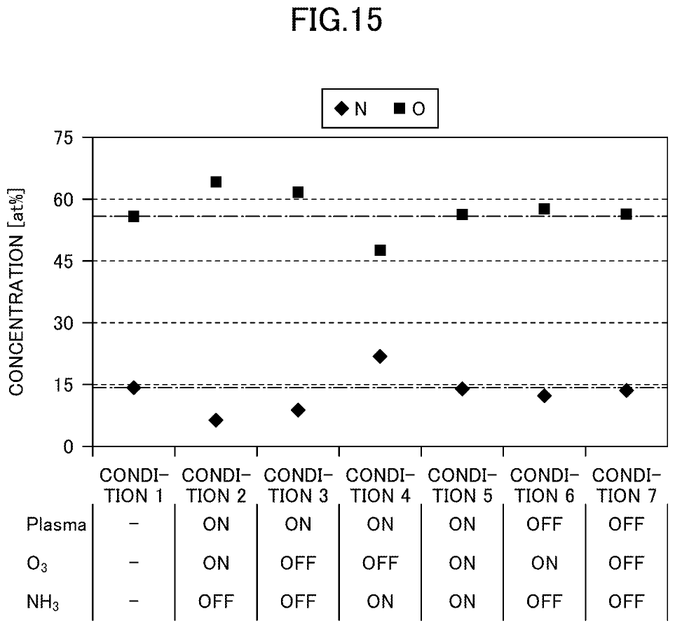

FIG. 15 is a drawing illustrating the concentration of nitrogen and the concentration oxygen in each of the SiON films, which are calculated based on FIG. 14. In FIG. 15, a diamond mark indicates the concentration of nitrogen (N) and a square mark indicates the concentration of oxygen (O).

As illustrated in FIG. 15, it can be seen that the concentration of nitrogen in the SiON film in each of the conditions 2 and 3 is lower than that of the condition 1. That is, it can be seen that the concentration of nitrogen in the SiON film becomes lower when Ar gas is supplied from the third processing gas nozzles 33 to 35 in the plasma annealing process S2 than when the plasma annealing process S2 is not performed. In particular, it can be seen that the concentration of nitrogen in the SiON film in the condition 2 is lower than that of the condition 3. That is, it can be seen that the concentration of nitrogen in the SiON film becomes lower when O₃ gas is supplied from the second processing gas nozzle 32 in the plasma annealing process S2 than when O₃ gas is not supplied from the second processing gas nozzle 32 in the plasma annealing process S2.

Further, as illustrated in FIG. 15, it can be seen that the concentration of nitrogen in the SiON film in the condition 4 is higher than that of the condition 1. That is, it can be seen that the concentration of nitrogen in the SiON film becomes higher when O₃ gas is not supplied from the second processing gas nozzle 32 and Ar gas and NH₃ gas are supplied from the third processing gas nozzles 33 to 35 in the plasma annealing process S2 than when the plasma annealing process S2 is not performed.

The above results indicate that the concentration of nitrogen in a SiON film can be adjusted by switching to including NH₃ gas in a gas supplied from the third processing gas nozzles 33 to 35 or switching to not including NH₃ gas in the gas supplied from the third processing gas nozzles 33 to 35 in the plasma annealing process S2.

Further, as illustrated in FIG. 15, it can be seen that the concentration of nitrogen in the SiON film in the condition 5 substantially does not change as compared to that of the condition 1. That is, it can be seen that the concentration of nitrogen in the SiON film substantially does not change between when O₃ gas is supplied from the second processing gas nozzle 32 and Ar gas and NH₃ gas are supplied from the third processing gas nozzles 33 to 35 in the plasma annealing process S2 and when the plasma annealing process S2 is not performed. Therefore, it is considered that, in order to adjust the concentration of nitrogen in a SiON film in the plasma annealing process S2, it is required not to supply O₃ gas from the second processing gas nozzle 32.

Further, as illustrated in FIG. 15, it can be seen that the concentration of nitrogen in the SiON film in each of the conditions 6 and 7 substantially does not change as compared to that of the condition 1. That is, it can be seen that the concentration of nitrogen in the SiON film substantially does not change between when the annealing process in performed instead of the plasma annealing process S2 and when the annealing process is not performed. Therefore, it is considered that in order to adjust the concentration of nitrogen in a SiON film, it is required to perform the plasma annealing process S2.

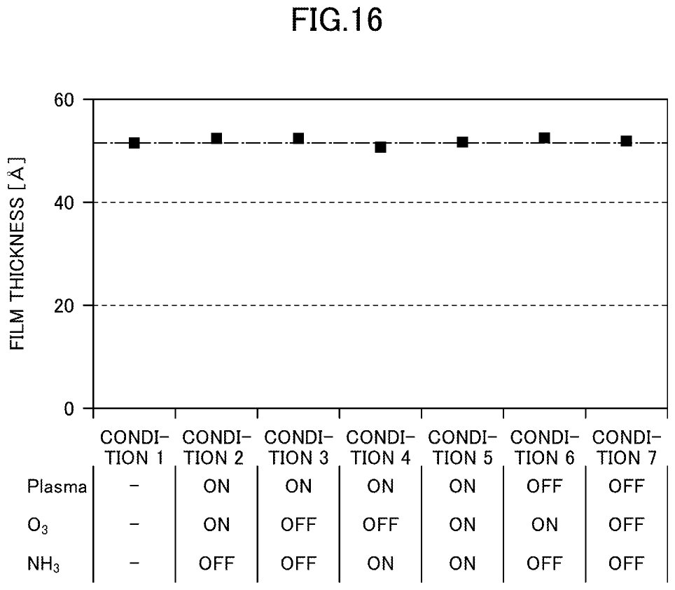

FIG. 16 is a drawing illustrating measurement results of the film thicknesses of the SiON films in the conditions 1 to 7.

As illustrated in FIG. 16, it can be seen that the film thicknesses of the SiON films in the conditions 1 to 7 are approximately the same. The results indicate that the presence or absence of the plasma annealing process S2, the presence or absence of the annealing process, and differences in the gases supplied from the third processing gas nozzles 33 to 35 in the plasma annealing process S2 have little influence on the film thicknesses of the SiON films. Although not illustrated, in-plane uniformities of the film thicknesses of the SiON films are approximately the same in the conditions 1 to 7. Therefore, it can also be said that the presence or absence of the plasma annealing process S2, the presence or absence of the annealing process, and differences in the gases supplied from the third processing gas nozzles 33 to 35 in the plasma annealing process S2 have little influence on the in-plane uniformities of the film thicknesses of the SiON films.

According to an aspect of the present disclosure, after a silicon oxynitride film is formed, the concentration of nitrogen in the silicon oxynitride film can be controlled.

The embodiments disclosed herein should be considered to be exemplary in all respects and not restrictive. The above-described embodiments may be omitted, substituted, or modified in various forms without departing from the appended claims.

In the above-described embodiments, the deposition apparatus is a semi-batch apparatus that processes a plurality of substrates disposed on a rotary table in a processing chamber by causing the substrate to revolve in accordance with the rotation of the rotary table and pass through a plurality of processing regions in turn; however, the present disclosure is not limited thereto. For example, the deposition apparatus may be a batch-type apparatus that processes a plurality of substrates at a time. Further, for example, the deposition apparatus may be a single-wafer deposition apparatus that processes substrates one by one.

In the above-described embodiments, the first processing gas is DIPAS gas; however, the present disclosure is not limited thereto. The first processing gas may be a gas including a silicon-containing gas, and may also include an inert gas such as Ar gas in addition to the silicon-containing gas. As the silicon-containing gas, an aminosilane-based gas, a silicon hydride gas, a halogen-containing silicon gas, or a combination thereof may be used. Examples of the aminosilane-based gas include di-isopropylamino silane (DIPAS) gas, tris-dimethylamino silane (3DMAS or TDMAS) gas, and bis tert-butylamino silane (BTBAS) gas. Examples of the silicon hydride gas include SiH₄ (MS) gas, Si₂H₆ (DS) gas, Si₃H₃ gas, and Si₄H₁₀ gas. Examples of the halogen-containing silicon gas include a fluorine-containing silicon gas such as SiF₄ gas, SiHF₃ gas, SiH₂F₂ gas, and SiH₃F gas; a chlorine-containing silicon gas such as SiCl₄ gas, SiHCl₃ gas, SiH₂Cl₂ (DOS) gas, SiH₃Cl gas, and Si₂Cl₆ gas; and a bromine-containing silicon gas such as SiBr₄ gas, SiHBr₃ gas, SiH₂Br₂ gas, and SiH₃Br gas.

In the above-described embodiments, the second processing gas is a mixed gas of O₃ gas and O₂ gas; however, the present disclosure is not limited thereto. The second processing gas may be a gas including an oxidizing gas, and may also include an inert gas such as Ar gas in addition to the oxidizing gas. As the oxidizing gas, O₂ gas, O₃ gas, H₂O gas, NO₂ gas, or a combination thereof may be used.

In the above-described embodiments, the third processing gas is a mixed gas of NH₃ gas and Ar gas; however, the present disclosure is not limited thereto. The third processing gas may be a gas including a nitriding gas. As the nitriding gas, ammonia (NH₃) gas, diazene (N₂H₂) gas, hydrazine (N₂H₄) gas, monomethylhydrazine (CH₃(NH)NH₂), or a combination thereof may be used.

In the above-described embodiments, the plasma generating gas is Ar gas or a mixed gas of Ar gas and NH₃ gas; however, the present disclosure is not limited thereto. For example, instead of the NH₃ gas, any other nitriding gas as described above may be used.

In the above-described embodiments, a SiON film is formed; however, the present disclosure is not limited thereto. For example, a film formed by the deposition method according to an embodiment may be a film including silicon (S1), oxygen (O), and nitrogen (N), and may also include any other element.

What is claimed is:

1. A deposition method comprising:
(a) forming a film including silicon (Si), oxygen (O), and nitrogen (N) on a substrate; and
(b) supplying a plasma generating gas including Ar gas and exposing the substrate having the film formed thereon to a first plasma generated from the plasma generating gas, wherein a concentration of the nitrogen in the film is adjusted by switching to including a nitriding gas in the plasma generating gas or switching to not including the nitriding gas in the plasma generating gas.

2. The deposition method according to claim 1, wherein (b) includes decreasing the concentration of the nitrogen in the film by not including the nitriding gas in the plasma generating gas.

3. The deposition method according to claim 1, wherein (b) includes increasing the concentration of the nitrogen in the film by including the nitriding gas in the plasma generating gas.

4. The deposition method according to claim 1, wherein (a) and (b) are alternately repeated.

5. The deposition method according to claim 1, wherein (a) includes repeating a cycle that includes
supplying a first processing gas including a silicon-containing gas to the substrate,
supplying a second processing gas including an oxidizing gas to the substrate, and
supplying a third processing gas including the nitriding gas to the substrate.

6. The deposition method according to claim 5, wherein the nitriding gas included in the plasma generating gas is same as the nitriding gas included in the third processing gas.

7. The deposition method according to claim 6, wherein the substrate is placed on an upper surface of a rotary table along a circumferential direction, the rotary table being provided in a vacuum chamber,
wherein a first processing gas supply configured to supply the first processing gas, a second processing gas supply configured to supply the second processing gas, and a third processing gas supply configured to supply the third processing gas or supply the first plasma generated from the plasma generating gas are provided above the rotary table in the vacuum chamber along a rotational direction of the rotary table,
wherein (a) is performed by rotating the rotary table in a state in which a second plasma is generated from the third processing gas while the first processing gas is supplied from the first processing gas supply, the second processing gas is supplied from the second processing gas supply, and the third processing gas is supplied from the third processing gas supply, and
wherein (b) is performed by rotating the rotary table in a state in which the first plasma is generated from the plasma generating gas while the plasma generating gas is supplied from the third processing gas supply without supplying the first processing gas from the first processing gas supply.

8. The deposition method according to claim 7, wherein (b) is performed while the second processing gas is supplied from the second processing gas supply.

9. A deposition apparatus comprising:
a rotary table provided in a vacuum chamber and having an upper surface, a plurality of substrates being placed on the upper surface of the rotary table along a circumferential direction;
a first processing gas supply configured to supply a first processing gas including a silicon-containing gas, a second processing gas supply configured to supply a second processing gas including an oxidizing gas, and a third processing gas supply configured to supply a third processing gas including a nitriding gas or supply a first plasma generated from a plasma generating gas including Ar gas, the first processing gas supply, the second processing gas supply, and the third processing gas supply being provided above the rotary table in the vacuum chamber along a rotational direction of the rotary table; and
a controller,
wherein the controller is configured to control the rotary table, the first processing gas supply, the second processing gas supply, and the third processing gas supply to perform a process including
forming a film including silicon (Si), oxygen (O), and nitrogen (N) on each of the substrates by rotating the rotary table in a state in which a second plasma is generated from the third processing gas while the first processing gas is supplied from the first processing gas supply, the second processing gas is supplied from the second processing gas supply, and the third processing gas is supplied from the third processing gas supply, and
exposing each of the substrates having the film formed thereon to the first plasma generated from the plasma generating gas by rotating the rotary table in a state in which the first plasma is generated from the plasma generating gas while the plasma generating gas is supplied from the third processing gas supply without supplying the first processing gas from the first processing gas supply, wherein a concentration of the nitrogen in the film is adjusted by switching to including a nitriding gas in the plasma generating gas or switching to not including the nitriding gas in the plasma generating gas.
